(19) United States
(12) Patent Application Publication
(10) Pub. No.: US 2026/0206610 A1
(43) Pub. Date: Jul. 16, 2026

(54) MANUFACTURING METHOD FOR MULTILAYER STRUCTURE WITH THROUGH GLASS VIAS FOR PACKAGING

(71) Applicant: E&R ENGINEERING CORPORATION, KAOHSIUNG CITY (TW)

(72) Inventor: SCHANG-JING HON, KAOHSIUNG CITY (TW)

(21) Appl. No.: 19/018,040

(22) Filed: Jan. 13, 2025

(30) Foreign Application Priority Data
Jan. 13, 2025 (TW) 114101266

(51) Int. Cl. H01L 21/48

(52) U.S. Cl. CPC H10W 70/095; H10W 99/00

(57) ABSTRACT

A manufacturing method for multilayer structure with through glass vias for packaging is disclosed. The method comprises forming a major substrate and forming at least one minor substrate on the major substrate, wherein steps for forming the major substrate comprises providing a major glass plate, forming a first major insulation layer, forming a major surface metal layer, forming a major via metal layer, and forming a second major insulation layer, wherein the major via metal layer is electrically connected with the major surface metal layer; each minor substrate has a minor surface metal layer and a minor via metal layer electrically connected with the minor surface metal layer and the major surface metal layer.

### CROSS REFERENCE TO RELATED APPLICATIONS

This non-provisional application claims the benefit under 35 U.S.C. §119(a) to Patent Application No. 114101266 filed in Taiwan on Jan. 13, 2025, which is hereby expressly incorporated by reference into the present application.

### BACKGROUND OF THE INVENTION

### 1. Field of the Invention

The present invention relates to packaging technology, especially to a manufacturing method for multilayer structure with through glass vias (TGV) for packaging.

### 2. Description of the Related Art

In the past, semiconductor chips are mostly processed by technologies such as wire bonding, flip chip, etc. for two-dimensional packaging (2D Packaging). However, with developments of artificial intelligence, 5G communications, and other fields in recent years, and also because sizes of electronic products (such as smartphones) have become increasingly thinner and lighter, the semiconductor chip must meet requirements of high computing ability, multi-function, low cost, etc. in a limited packaging space. That is, pattern circuits on the semiconductor chip are becoming increasingly refined, resulting in that the two-dimensional packaging no fulfills current requirements. Therefore, three-dimensional packaging through vertical interconnections is developed to achieve high performance of the semiconductor chip.

A CoWoS (Chip-on-Wafer-on-substrate) can be used in the three-dimensional packaging, wherein the CoWoS comprises an interposer and a substrate. Material of a conventional interposer mainly is silicon (Si) or polyimide (PI). The conventional interposer made solely from silicon can achieve a required wire density but is not cost-effective. The conventional interposer made solely from polyimide can meet a low-cost requirement but is only for low-power semiconductor chips. Therefore, a hybrid interposer made of silicon and polyimide is developed to fulfill requirements of wire density and low cost at the same time. A conventional substrate is mainly an Ajinomoto Build-up Film (ABF) substrate, a Bismaleimide Triazine (BT) substrate, etc.

However, coefficients of thermal expansion (CTEs) of the conventional hybrid interposer and the conventional substrate have a large difference from the CTE of the semiconductor chip. When the semiconductor chip is computing, heat generated by the semiconductor chip causes stress in the interposer or the substrate. Assuming that the difference between the CTEs is too large, the interposer or the substrate may have warpage problems. Performances of the semiconductor chips will be affected as a result, such that reliabilities of packaging components have instability problems.

### SUMMARY OF THE INVENTION

In view of this, the present invention provides a manufacturing method for multilayer structure with through glass vias for packaging to reduce generation of stress and improve the reliabilities of the packaging components.

In order to achieve the aforementioned purpose, the manufacturing method for multilayer structure with through glass vias for packaging of the present invention comprises:
forming a major substrate comprising:
   providing a major glass plate, wherein the major glass plate has at least one major through via in an interior of the major glass plate, and the at least one major through via communicates with a top surface and a bottom surface of the major glass plate;
   forming a first major insulation layer on the top surface of the major glass plate, the bottom surface of the major glass plate, and an inner wall of the at least one major through via;
   forming a major surface metal layer on the first major insulation layer that is located on the top surface and the bottom surface of the major glass plate, and forming a major via metal layer on the first major insulation layer that is located on the inner wall of the at least one major through via, wherein the major via metal layer is electrically connected with the major surface metal layer; and
   forming a second major insulation layer on the first major insulation layer and the major surface metal layer, wherein the second major insulation layer and the first major insulation layer jointly form a major insulation layer; and
forming at least one minor substrate on the major substrate, wherein each minor substrate has a minor surface metal layer and a minor via metal layer electrically connected with the minor surface metal layer and the major surface metal layer.

The multilayer structure made by the present invention can be adopted as a substrate and an interposer in three-dimensional packaging. Since the multilayer structure of the present invention uses glass as main material with the CTE (coefficients of thermal expansion) similar to the CTE of semiconductor chips, the present invention can reduce stress generated by heat and reduce warpage problems, thereby stabilizing the reliabilities of the packaging components.

### BRIEF DESCRIPTION OF THE DRAWINGS

FIG. 1 is a cross-sectional view of a glass plate of the multilayer structure with through glass vias for packaging of the present invention;

FIGS. 2A to 2K are schematic views of manufacturing processes of a first embodiment of the glass plate of the multilayer structure of the present invention; and

FIGS. 3A to 3E are schematic views of manufacturing processes of a second embodiment of the glass plate of the multilayer structure of the present invention.

### DETAILED DESCRIPTION OF THE INVENTION

In order to understand the technical characteristics and practical effects of the prevent invention in detail, and accomplish them according to the content of the present invention, the detailed description is as follows with the embodiments shown in the figures.

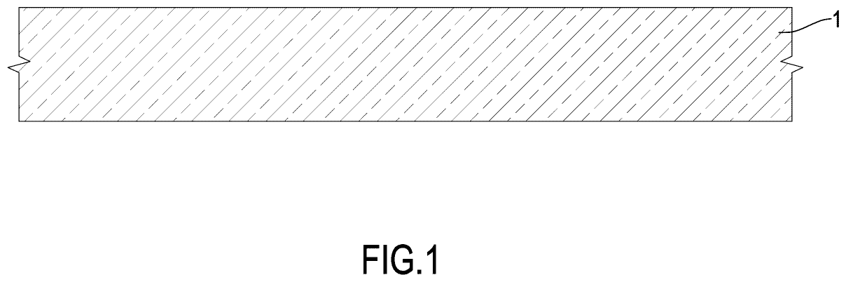

The present invention is a manufacturing method for multilayer structure with through glass vias (TGV) for packaging. Referring to FIG. 1, FIG. 1 depicts a glass plate 1 that has not been processed yet. The present invention may produce the multilayer structure with through glass vias for packaging by processing the glass plate 1 and stacking multiple processed glass plates. Manufacturing methods and the structure of the multiplayer structure with through glass vias for packaging of the present invention are described with the drawings as follows.

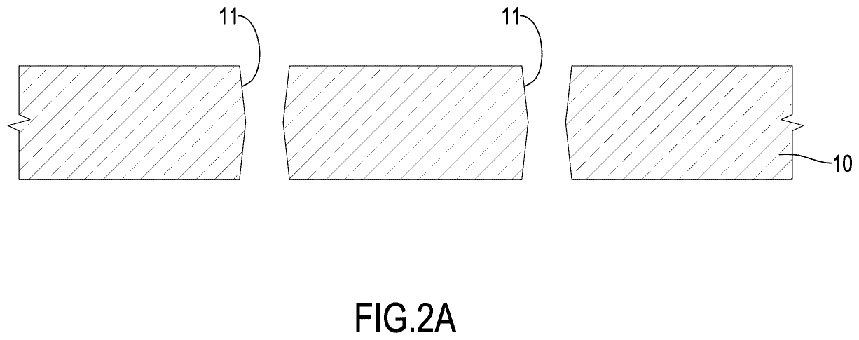

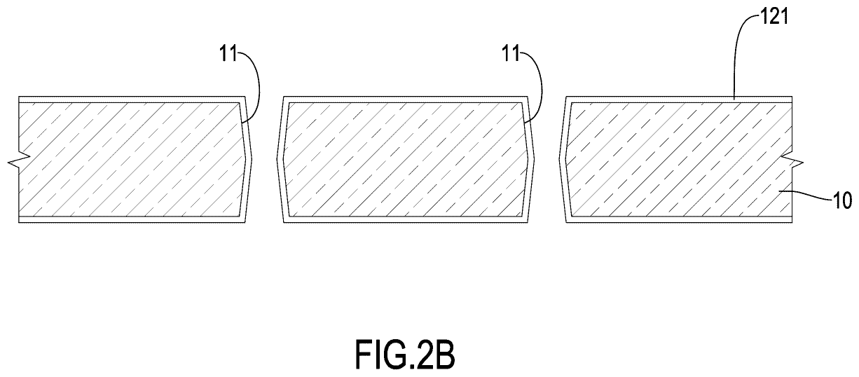

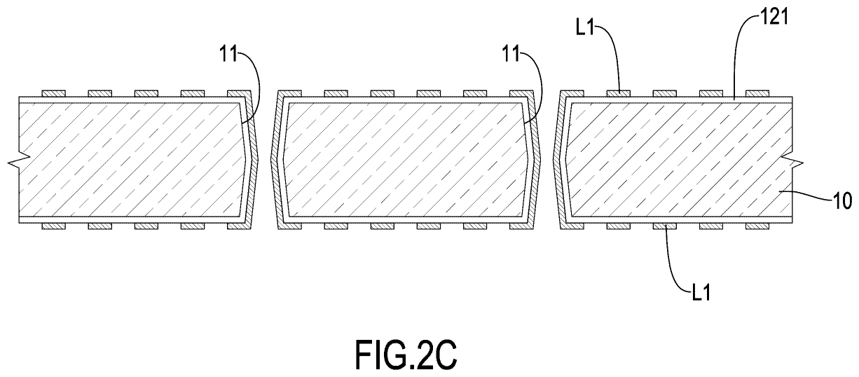

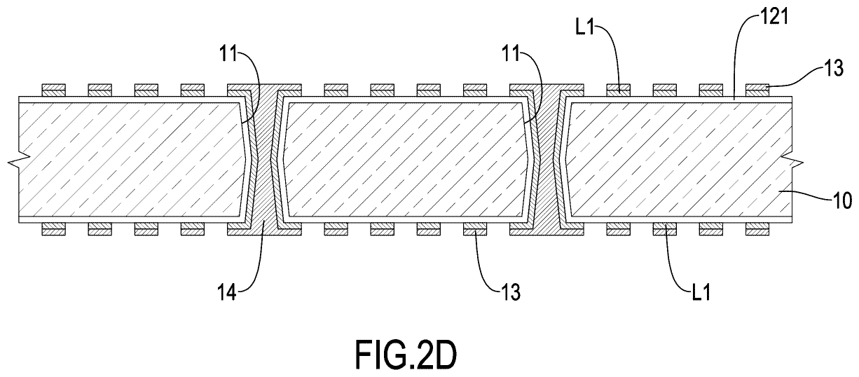

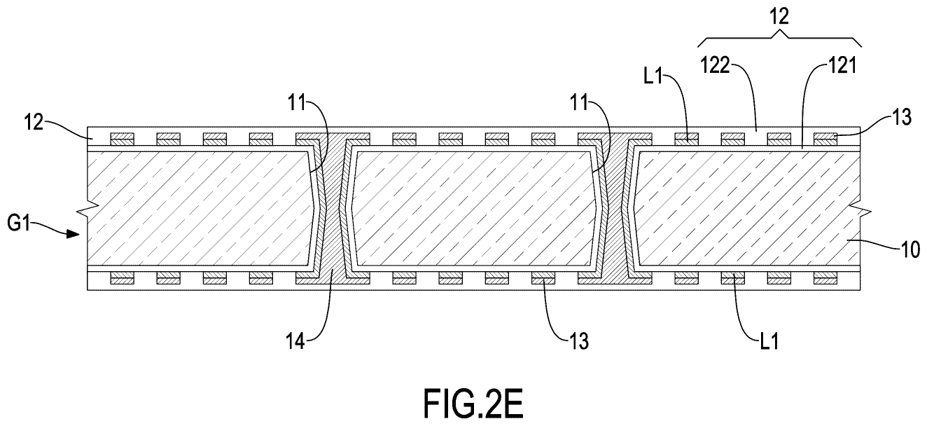

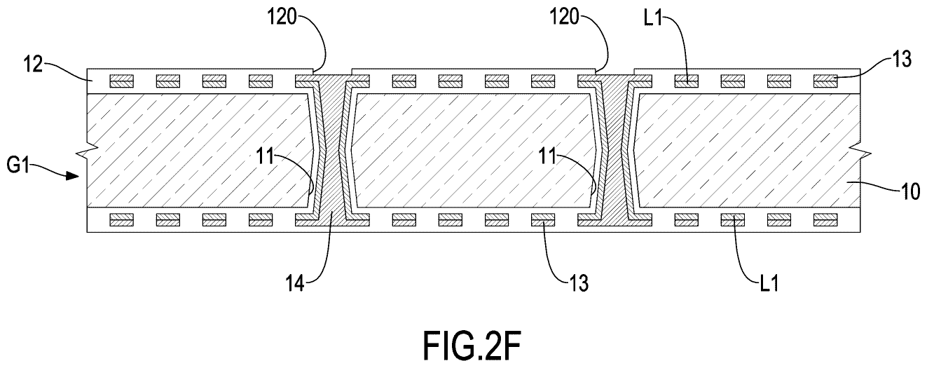

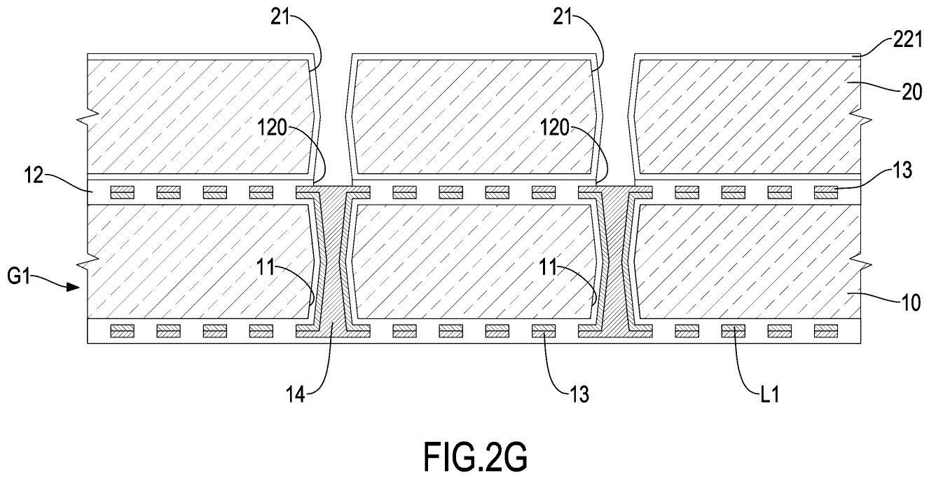

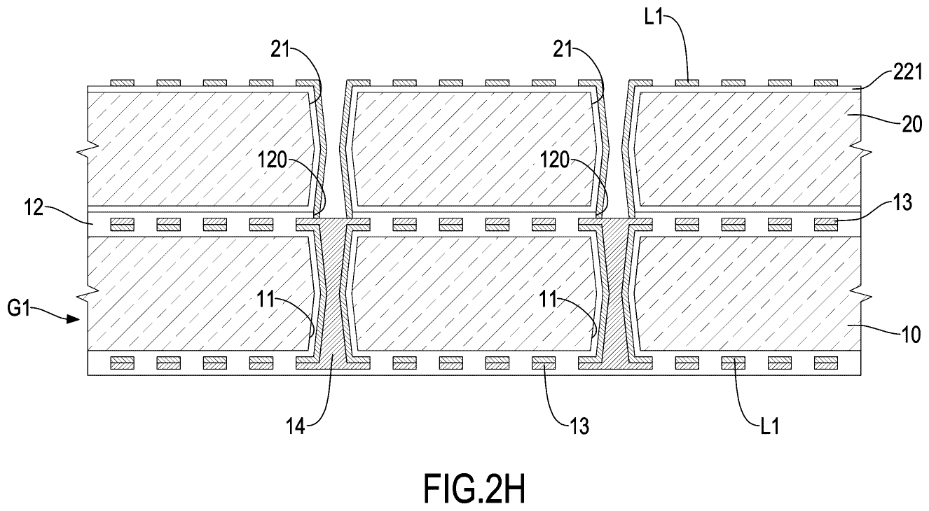

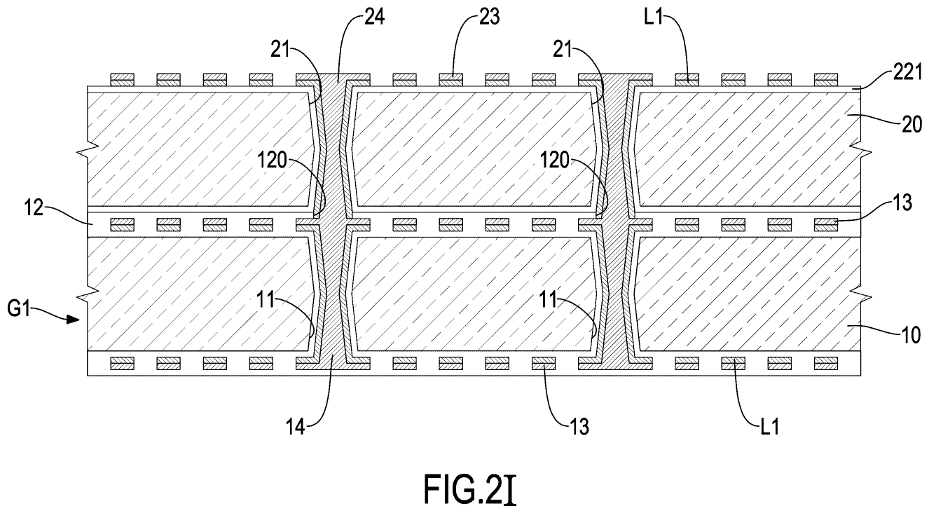

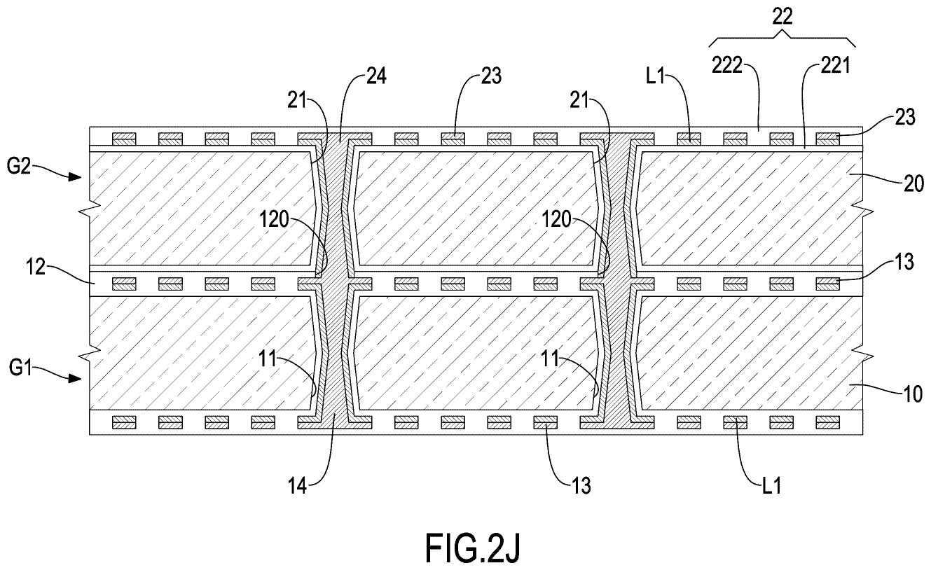

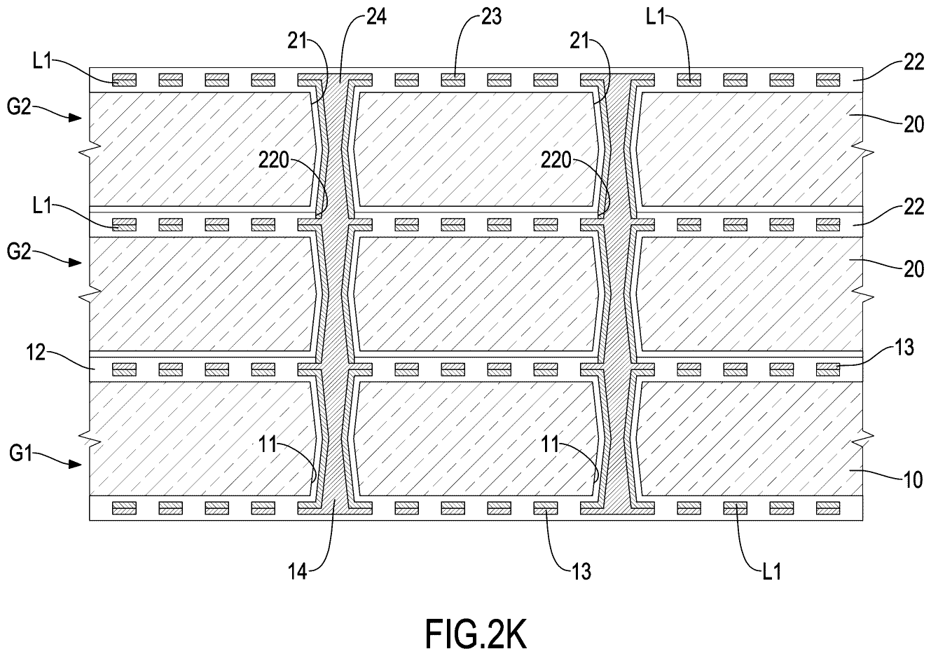

The manufacturing method for the multilayer structure with through glass vias for packaging comprises forming a major substrate G1 as shown in FIG. 2E and forming at least one minor substrate G2 as shown in FIG. 2K on the major substrate G1. Steps of forming the major substrate G1 include steps as shown in FIGS. 2A to 2E.

Referring to FIG. 2A, a major glass plate 10 is provided. At least one major through via 11 is formed in an interior of the major glass plate 10, and the at least one major through via 11 communicates with a top surface and a bottom surface of the major glass plate 10. For example, a laser modification process and an etching process can be performed on the top surface of the major glass plate 10 to form the at least one major through via 11 extending to the bottom surface of the major glass plate 10 from the top surface of the major glass plate 10.

Referring to FIG. 2B, a first major insulation layer 121 is formed on the top surface of the major glass plate 10, the bottom surface of the major glass plate 10, and an inner wall of the at least one major through via 11. For example, a material of the first major insulation layer 121 can be polyimide (PI), and the first major insulation layer 121 can be formed by a dipping process.

Referring to FIGS. 2C and 2D, a major surface metal layer 13 is formed on the first major insulation layer 121 that is located on the top surface and the bottom surface of the major glass plate 10, and a major via metal layer 14 is formed on the first major insulation layer 121 that is located on the inner wall of the at least one major through via 11. For example, the major surface metal layer 13 and the major via metal layer 14 are formed by an electroless plating process. There is a seed layer L1 formed between the major surface metal layer 13 and the first major insulation layer 121 and between the major via metal layer 14 and the first major insulation layer 121 respectively, wherein the seed layer L1 and the major surface metal layer 13 form a pattern circuit. For example, the seed layer L1 can be formed on the first major insulation layer 121 by a sputtering process, and then a metal layer can be formed on the seed layer L1. The metal layer located on the top surface and the bottom surface of major glass plate 10 is defined as the major surface metal layer 13, and the metal layer located on the inner wall of the at least one major through via 11 is defined as the major via metal layer 14, wherein the major surface metal layer 13 is electrically connected with the major via metal layer 14. In addition, the material of the seed layer L1 can be metal such as nickel (Ni), chromium (Cr), etc., and the material of the major surface metal layer 13 and the major via metal layer 14 can be copper (Cu). The present invention is not limited to the foregoing examples.

Referring to FIG. 2E, a second major insulation layer 122 is formed on the first major insulation layer 121 and the major surface metal layer 13, wherein the second major insulation layer 122 and the first major insulation layer 121 jointly form a major insulation layer 12. For example, the material of the second major insulation layer 122 can also be polyimide (PI), and the second major insulation layer 122 can be formed by the dipping process. In addition, the first major insulation layer 121 and the second major insulation layer 122 can be heat-melted together to form the major insulation layer 12.

After completing the processes shown in FIGS. 2A to 2E, the major substrate G1 (as shown in FIG. 2E) of the multilayer structure with through glass vias for packaging of the present invention is formed. That is, the major substrate G1 comprises the major glass plate 10, the major insulation layer 12, the major surface metal layer 13, and the major via metal layer 14. The interior of the major glass plate 10 comprises the at least one major through via 11. The major insulation layer 12 covers the top surface of the major glass plate 10, the bottom surface of the major glass plate 10, and the inner wall of the at least one major through via 11. The major surface metal layer 13 is wrapped in the major insulation layer 12 that is located on the top surface and the bottom surface of the major glass plate 10. The major via metal layer 14 is mounted on the major insulation layer 12 that is located on the inner wall of the at least one major through via 11.

In an embodiment of the present invention, referring to FIG. 2E, the major surface metal layer 13 includes a first major surface metal layer and a second major surface metal layer. The first major surface metal layer is wrapped in the major insulation layer 12 that is located on the top surface of the major glass plate 10, and the second major surface metal layer is wrapped in the major insulation layer 12 that is located on the bottom surface of the major glass plate 10. The first major surface metal layer is electrically connected with the second major surface metal layer by the major via metal layer 14.

The subsequent process of the manufacturing method for the multilayer structure with through glass vias for packaging of the present invention is to form the at least one minor substrate G2 on the major substrate G1. Referring to FIG. 2F, before forming the at least one minor substrate G2 on the major substrate G1, at least one major-minor opening 120 is formed on the major insulation 12 that is located on at least one of the top surface and the bottom surface of the major substrate G1. The position of the at least one major-minor opening 120 may correspond to the position of the major surface metal layer 13 to expose a part of the major surface metal layer 13. For example, the at least one major-minor opening 120 can be formed by a lasering process, an etching process, etc. The present invention is not limited to the foregoing examples.

The subsequent steps of the manufacturing method of the multilayer structure with through glass vias for packaging of the present invention can include a first embodiment and a second embodiment. The difference between the first and second embodiments is: the structure manufactured by the first embodiment is not mounted with a chip, and the structure manufactured by the second embodiment is mounted with a chip.

In the first embodiment, for example, the at least one minor substrate G2 comprises a minor substrate G2. The steps for forming the minor substrate G2 are described with the drawings as follows.

Referring to FIG. 2G, a minor glass plate 20 formed with a first minor insulation layer 221 is stacked on the major insulation layer 12 that is located on at least one of the top surface and the bottom surface of the major substrate G1. In particular, pre-processing steps for the minor glass plate 20 are performed at first. The pre-processing steps include: providing the minor glass plate 20 comprising at least one minor through via 21 inside, forming the first minor insulation layer 221 on a top surface of the minor glass plate 20, a bottom surface of the minor glass plate 20, and an inner wall of the at least one minor through via 21, wherein the at least one minor through via 21 communicates with the top surface and the bottom surface of the minor glass plate 20. For example, the at least one minor through via 21 can be formed by the laser modification process and the etching process, and a material of the first minor insulation layer 221 can be polyimide. Then, stack the minor glass plate 20 formed with the first minor insulation layer 221 on at least one of the top surface and the bottom surface of the major substrate G1 (the major insulation layer 12).

Referring to FIGS. 2H and 2I, a minor surface metal layer 23 is formed on the first minor insulation layer 221 that is located on the top surface of the minor glass plate 20, and a minor via metal layer 24 is formed on the first minor insulation layer 222 that is located on the inner wall of the at least one minor through via 21. The process to form the minor surface metal layer 23 and the minor via metal layer 24 is the same as the process (the electroless plating process) to form the major surface metal layer 13 and the major via metal layer 14, which will not be described again. Similarly, a seed layer L1 is also formed between the minor surface metal layer 23 and the first minor insulation layer 221 and between the minor via metal layer 24 and the first minor insulation layer 221. The material of the minor surface metal layer 23 and the minor via metal layer 24 can be copper (Cu). The present invention is no limited to the foregoing example.

The minor via metal layer 24 is electrically connected with the minor surface metal layer 23 and the major surface metal layer 13. In the present embodiment, the position of the at least one minor through via 21 may correspond to the position of the at least one major-minor opening 120, so that the position of the minor via metal layer 24 formed in the at least one minor through via 21 corresponds to the position of the major surface metal layer 13 of the major substrate G1 to form electrical connections. Alternatively, the minor via metal layer 24 is electrically connected with the major surface metal layer 13 through a redistribution layer (RDL) (not shown in the drawings).

Referring to FIG. 2J, a second minor insulation layer 222 is formed on the first minor insulation layer 221 that is located on the top surface of the minor glass plate 20 and the minor surface metal layer 23. For example, the material of the second minor insulation layer 222 also can be polyimide, and the second minor insulation layer 222 can be formed by the dipping process. The first minor insulation layer 221 and the second minor insulation layer 222 can be heat-melted together to form a minor insulation layer 22.

After completing the processes shown in FIGS. 2A to 2J, the first embodiment of the multilayer structure with through glass vias for packaging of the present invention is formed (as shown in FIG. 2J). That is, the multilayer structure comprises the major substrate G1 and the at least one minor substrate G2. Each minor substrate G2 comprises the minor glass plate 20, the minor insulation layer 22, the minor surface metal layer 23, and the minor via metal layer 24. The interior of the minor glass plate 20 comprises the at least one minor through via 21. The minor insulation layer 22 covers the top surface of the minor glass plate 20, the bottom surface of the minor glass plate 20, and the inner wall of the at least minor through via 21. The minor surface metal layer 23 is wrapped in the minor insulation layer 22 that is located on the top surface of the minor glass plate 20. The minor via metal layer 24 is mounted on the minor insulation layer 22 that is located on the inner wall of the at least one minor through via 21.

Referring to FIG. 2K, in the preset embodiment, another minor substrate G2 (hereinafter referred to as a latter minor substrate G2) can be mounted on the foregoing minor substrate G2 (hereinafter referred to as a former minor substrate G2). The steps to form the latter minor substrate G2 is as aforementioned and will not be described again. Please note that a step is included before forming the two adjacent minor substrates G2. The step is to form at least one minor-minor opening 220 on the minor insulation layer 22 of the former minor substrate G2. The position of the at least one minor-minor opening 220 may correspond to the position of the minor surface metal layer 23 to expose a part of the minor surface metal layer 23. For example, the at least one minor-minor opening 220 can be formed by the lasering process, the etching process, etc. The present invention is not limited to the foregoing examples.

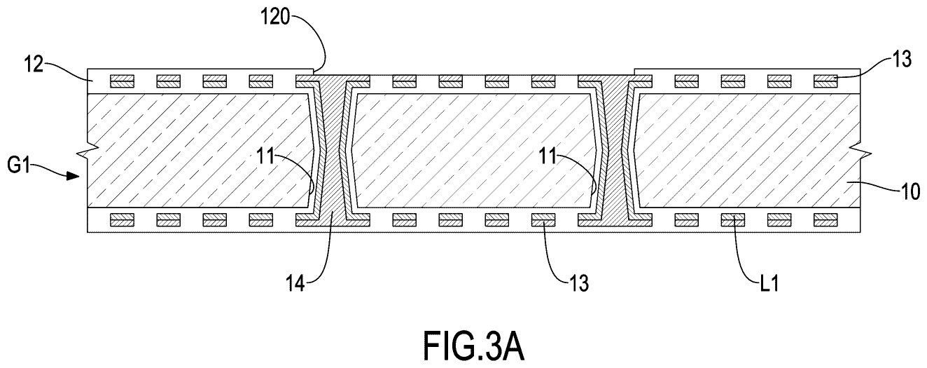

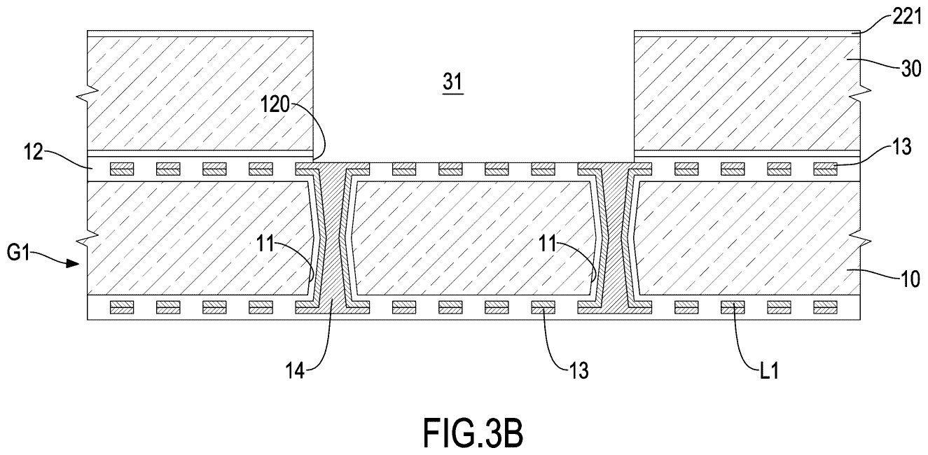

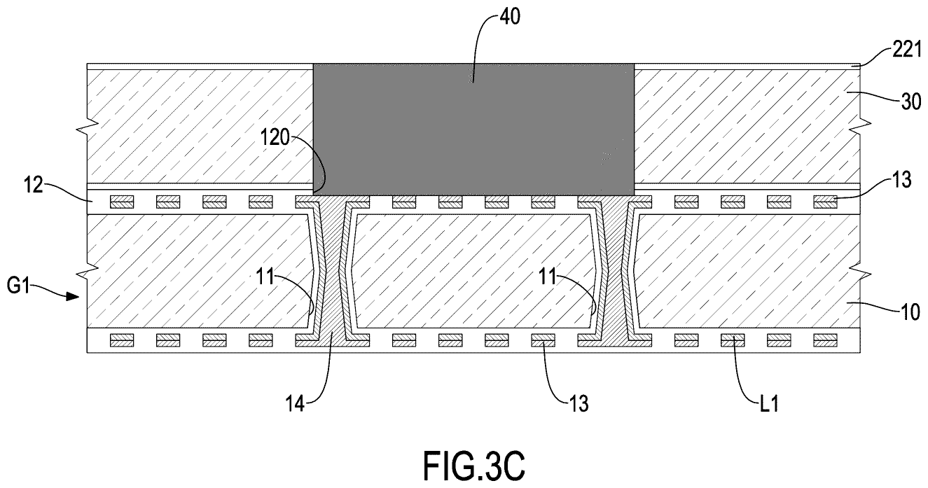

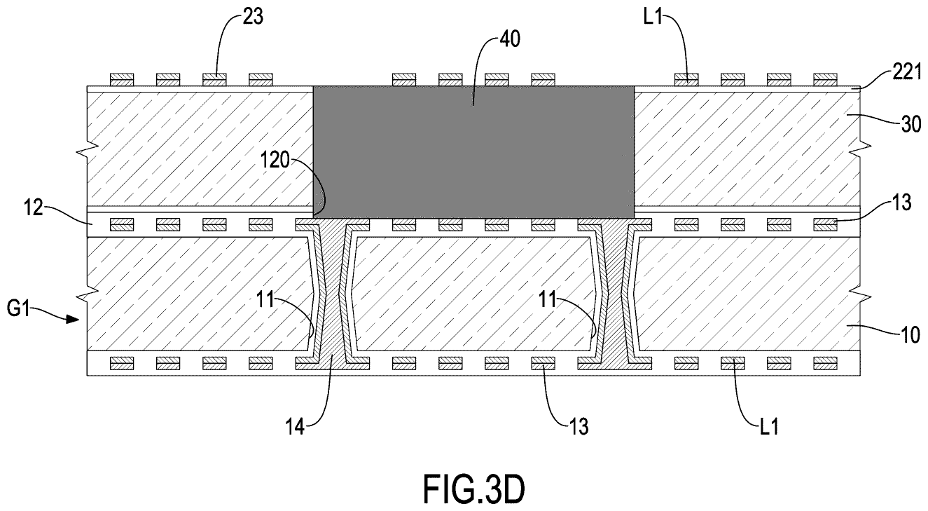

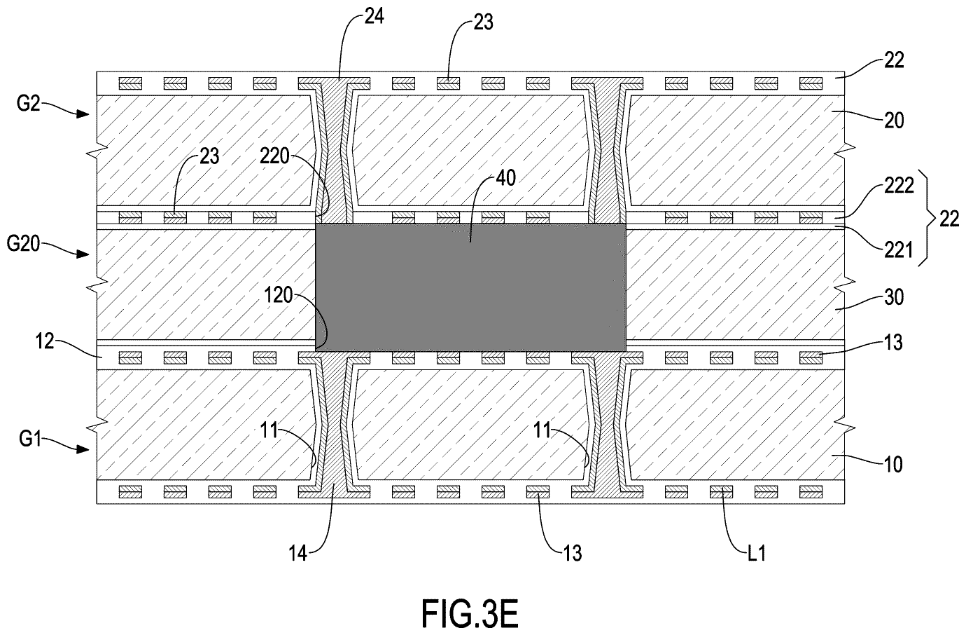

In the second embodiment, the at least one minor substrate G2 includes a chip minor substrate G20 as shown in FIG. 3E. The steps for forming the chip minor substrate G20 are described with the drawings as follows.

Referring to FIG. 3A, after forming the major substrate G1 as shown in FIG. 2E, the at least one major-minor opening 120 is formed on the major insulation layer 12. Referring to 3B, a chip minor glass plate 30 with an accommodating cavity 31 is stacked on the major insulation layer 12 that is located on at least one of the top surface and the bottom surface of the major substrate G1. Specifically, pre-processing steps for the chip minor glass plate 30 are performed at first. The pre-processing steps include: forming the first minor insulation layer 221 on the top surface and the bottom surface of the chip minor glass plate 30, forming the accommodating cavity 31 in the interior of the chip minor glass plate 30, wherein the accommodating cavity 31 communicates with the top surface and the bottom surface of the chip minor glass plate 30. For example, the accommodating cavity 31 can be formed by the laser modification process and the etching process. Then, a next step is to stack the chip minor glass plate 30 with the accommodating cavity 31 on the major substrate G1, and the position of the accommodating cavity 31 may correspond to the position of the at least one major-minor opening 120.

Although the position of the at least one minor through via 21 is not shown in FIG. 3B, it does not mean that the chip minor glass plate 30 does not comprise the at least one minor through via 21. In the present embodiment, the chip minor glass plate 30 may also comprise the at least one minor through via 21.

Referring to FIG. 3C, a chip 40 is mounted in the accommodating cavity 31. Preferably, after the accommodating cavity 31 is mounted with the chip 40, a molding layer (not shown in the drawings) can be filled in the space outside the chip 40 in the accommodating cavity 31. For example, a material of the molding layer can be resin. Referring to FIG. 3D, the minor surface metal layer 23 is formed on the first minor insulation 221 that is located on the top surface of the chip minor glass plate 30 and the chip 40, wherein the process to form the minor surface metal layer 23 is as aforementioned and will not be described again. Since the position of the accommodating cavity 31 corresponds to the position of the at least one major-minor opening 120, the chip 40 is electrically connected with the major surface metal layer 13 and the minor surface metal layer 23 of the chip minor substrate G20.

Referring to FIG. 3E, the second minor insulation layer 22 is formed on the first minor insulation layer 221 that is located on the top surface of the chip minor glass plate 30, the minor surface metal layer 23, and the chip 40. The first minor insulation layer 221 and the second minor insulation layer 222 can be heat-melted together to form a minor insulation layer 22. In the present invention, at least one minor substrate G2 can be formed on the chip minor substrate G20. For example, taking a minor substrate G2 formed on the chip minor substrate G20 as an example, the steps to form the minor substrate G2 are as aforementioned and comprise: forming the at least one minor-minor opening 220 on the minor insulation layer 22 of the chip minor substrate G20, providing a minor glass plate 20, forming the first minor insulation layer 221 on the top surface of the minor glass plate 20, the bottom surface of the minor glass plate 20, and the inner wall of the at least one minor through via 21, stacking the minor glass plate 20 formed with the first minor insulation layer 221 on the minor insulation layer 22 of the chip minor substrate G20, forming the minor surface metal layer 23 on the first minor insulation layer 221 that is located on the top surface of the minor glass plate 20, forming the minor via metal layer 24 on the first minor insulation layer 221 that is located on the inner wall of the at least one minor through via 21 of the minor glass plate 20, and forming the second minor insulation layer 222 on the first minor insulation layer 221 and the minor surface metal layer 23 on the minor glass plate 20. Moreover, the position of the at least one minor-minor opening 220 corresponds to the position of the chip 40 to expose a part of the chip 40. The position of the at least one minor through via 21 corresponds to the position of the at least one minor-minor opening 220, so that the minor via metal layer 24 of the minor substrate G2 is electrically connected with the chip 40 and the minor surface metal layer 23 of the minor substrate G2.

The multilayer structure with through glass vias for packaging made by the present invention can be adopted as a substrate and an interposer in three-dimensional packaging. Since the multilayer structure of the present invention uses glass as main material with the CTE (coefficients of thermal expansion) similar to the CTE of semiconductor chips, the present invention can reduce stress generated by heat and reduces warpage problems, thereby stabilizing the reliabilities of the packaging components.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A manufacturing method for a multilayer structure with through glass vias for packaging, comprising:
forming a major substrate comprising:
providing a major glass plate, wherein the major glass plate has at least one major through via in an interior of the major glass plate, and the at least one major through via communicates with a top surface and a bottom surface of the major glass plate;
forming a first major insulation layer on the top surface of the major glass plate, the bottom surface of the major glass plate, and an inner wall of the at least one major through via;
forming a major surface metal layer on the first major insulation layer that is located on the top surface and the bottom surface of the major glass plate, and forming a major via metal layer on the first major insulation layer that is located on the inner wall of the at least one major through via, wherein the major via metal layer is electrically connected with the major surface metal layer; and
forming a second major insulation layer on the first major insulation layer and the major surface metal layer, wherein the second major insulation layer and the first major insulation layer jointly form a major insulation layer; and
forming at least one minor substrate on the major substrate, wherein each minor substrate has a minor surface metal layer and a minor via metal layer electrically connected with the minor surface metal layer and the major surface metal layer.

2. The manufacturing method for a multilayer structure with through glass vias for packaging as claimed in claim 1, wherein:
the major surface metal layer, the major via metal layer, the minor surface metal layer and the minor via metal layer of each minor substrate are formed by an electroless plating process.

3. The manufacturing method for a multilayer structure with through glass vias for packaging as claimed in claim 1 further comprising a step as follows before forming the at least one minor substrate:
forming at least one major-minor opening on the major insulation layer that is located on at least one of the top surface and the bottom surface of the major substrate, wherein a position of the at least one major-minor opening corresponds to a position of the major surface metal layer to expose a part of the major surface metal layer.

4. The manufacturing method for a multilayer structure with through glass vias for packaging as claimed in claim 3, wherein the at least one minor substrate comprises a minor substrate, and steps to form the minor substrate comprise:
providing a minor glass plate having at least one minor through via in an interior of the minor glass plate, wherein the at least one minor through via communicates with a top surface and a bottom surface of the minor glass plate;
forming a first minor insulation layer on the top surface of the minor glass plate, the bottom surface of the minor glass plate, and an inner wall of the minor glass plate;
stacking the minor glass plate formed with the first minor insulation layer on the major insulation layer that is located on the at least one of the top surface and the bottom surface of the major substrate, wherein a position of the at least one minor through via corresponds to a position of the at least one major-minor opening;
forming the minor surface metal layer on the first minor insulation layer that is located on the top surface of the minor glass plate, and forming the minor via metal layer on the first minor insulation layer that is located on the inner wall of the at least one minor through via; and
forming a second minor insulation layer on the first minor insulation layer and the minor surface metal layer that is located on the top surface of the minor glass plate, wherein the second minor insulation layer and the first minor insulation layer jointly form a minor insulation layer.

5. The manufacturing method for a multilayer structure with through glass vias for packaging as claimed in claim 4 further comprising a step as follows before forming two adjacent said minor substrates:
forming at least one minor-minor opening on the minor insulation layer, wherein a position of the at least one minor-minor opening corresponds to a position of the minor surface metal layer to expose a part of the minor surface metal layer.

6. The manufacturing method for a multilayer structure with through glass vias for packaging as claimed in claim 3, wherein the at least one minor substrate includes a chip minor substrate, and steps to form the chip minor substrate comprise:
forming a first minor insulation layer on a top surface and a bottom surface of a chip minor glass plate;
forming an accommodating cavity in an interior of the chip minor glass plate, wherein the accommodating cavity communicates with the top surface and the bottom surface of the chip minor glass plate;
stacking the chip minor glass plate formed with the accommodating cavity on the major insulation layer that is located on at least one of the top surface and the bottom surface of the major substrate, wherein a position of the accommodating cavity corresponds to a position of the at least one major-minor opening;
mounting a chip in the accommodating cavity;
forming the minor surface metal layer on the first minor insulation layer that is located on the top surface of the chip minor glass plate and the chip; and
forming a second minor insulation layer on the first minor insulation layer that is located on the top surface of the chip minor glass plate, the minor surface metal layer, and the chip, wherein the second minor insulation layer and the first minor insulation layer jointly form a minor insulation layer;
wherein the chip is electrically connected with the major surface metal layer and the minor surface metal layer of the chip minor substrate.

7. The manufacturing method for a multilayer structure with through glass vias for packaging as claimed in claim 6, wherein a minor substrate is formed on the chip minor substrate, and steps to form the minor substrate comprise:
forming at least one minor-minor opening on the minor insulation layer, wherein a position of the at least one minor-minor opening corresponds to a position of the chip to expose a part of the chip;
providing a minor glass plate having at least one minor through via in an interior of the minor glass plate, wherein the at least one minor through via communicates with a top surface and a bottom surface of the minor glass plate;
forming the first minor insulation layer on the top surface of the minor glass plate, the bottom surface of the minor glass plate and an inner wall of the minor glass plate;
stacking the minor glass plate formed with the first minor insulation layer on the minor insulation layer that is located on the chip minor substrate, wherein a position of the at least one minor through via corresponds to a position of the at least one minor-minor opening;
forming the minor surface metal layer on the first minor insulation layer that is located on the top surface of the minor glass plate, and forming the minor via metal layer on the first minor insulation layer that is located on the inner wall of the at least one minor through via; and
forming the second minor insulation layer on the first minor insulation layer that is located on the top surface of the minor glass plate and the minor surface metal layer, wherein the second minor insulation layer and the first minor insulation layer jointly form the minor insulation layer;
wherein the minor via metal layer is electrically connected with the chip and the minor surface metal layer of the minor substrate.
